(19) United States
(12) Patent Application Publication
(10) Pub. No.: US 2016/0349621 A1
(43) Pub. Date: Dec. 1, 2016

(54) METHODS FOR TEXTURING A CHAMBER COMPONENT AND CHAMBER COMPONENTS HAVING A TEXTURED SURFACE

(71) Applicant: APPLIED MATERIALS, INC., Santa Clara, CA (US)

(72) Inventors: Xi HUANG, Shanghai (CN); Wenlong XU, Shanghai (CN)

(21) Appl. No.: 14/889,322

(22) PCT Filed: Dec. 15, 2014
(86) PCT No.: PCT/CN2014/093844

§ 371 Date: Nov. 5, 2015

(51) Int. Cl. G03F 7/40; C25F 3/06; C25F 3/14

(52) U.S. Cl. CPC G03F 7/40; C25F 3/14; C25F 3/06

(57) ABSTRACT

A method for a textured surface on a chamber component is provided and includes providing a chamber component, applying a layer of a photoresist to a surface of the chamber component, exposing a portion of the photoresist to optical energy using a mask to cure a portion of the photoresist, removing uncured photoresist from the surface, and electrochemically etching the chamber component to form a textured surface on the chamber component.

### BACKGROUND

1. Field

Embodiments disclosed herein generally relate to methods to modify a surface of a material. More particularly, embodiments disclosed herein relate to methods for modifying a surface of components used in a process chamber and provide a textured surface on chamber components.

2. Description of the Related Art

As integrated circuit devices continue to be fabricated with reduced dimensions, the manufacture of these devices become more susceptible to reduced yields due to contamination. Consequently, fabricating integrated circuit devices, particularly those having smaller physical sizes, requires that contamination be controlled to a greater extent than previously considered to be necessary.

Contamination of integrated circuit devices may arise from sources such as undesirable stray particles impinging on a substrate during thin film deposition, etching or other semiconductor fabrication processes. In general, the manufacturing of the integrated circuit devices includes the use of process chambers such as physical vapor deposition (PVD) chambers and sputtering chambers, chemical vapor deposition (CVD) chambers, plasma etching chambers, to name a few. During the course of deposition and etch processes, materials often condense from the gas phase and deposit onto various internal surfaces in the chamber to form solid masses on these surfaces of the chamber. This deposited matter accumulates on the internal surfaces of the chamber and is prone to detaching or flaking off of the internal surfaces in between or during a substrate process sequence. The detached matter may then impinge upon and contaminate the substrate and devices thereon. Contaminated devices frequently must be discarded, thereby decreasing the manufacturing yield of the process.

In order to circumvent the problems associated with detached matter, chamber surfaces require frequent, and sometimes time-consuming, cleaning steps to remove deposited matter from the chamber surfaces. Also, despite the amount of cleaning that is performed, in some instances, contamination from detached matter may still occur.

Therefore, there is a need to reduce contamination from matter that has deposited on interior surfaces of a process chamber.

SUMMARY

A method for a textured surface on a chamber component is provided one embodiment. The method includes providing a chamber component, applying a layer of a photoresist to a surface of the chamber component, exposing a portion of the photoresist to optical energy using a mask to cure a portion of the photoresist, removing uncured photoresist from the surface, and electrochemically etching the chamber component to form a textured surface on the chamber component.

In another embodiment, a chamber component for a processing chamber is provided. The component comprises a textured surface comprising a plurality of textured features formed by an electrochemical etching process. Each of the textured features comprise a plurality of raised features surrounding and/or circumscribed by a plurality grooves, and at least a portion of the grooves intersect.

### BRIEF DESCRIPTION OF THE DRAWINGS

So that the manner in which the above-recited features, advantages and objects of the present invention are attained can be understood in detail, a more particular description of the invention, briefly summarized above, may be had by reference to the embodiments thereof which are illustrated in the appended drawings.

FIG. 1 is a simplified schematic cross-sectional illustration of a process chamber having chamber components with a textured surface as described herein.

FIGS. 2A-2H are schematic views illustrating a process for forming a textured surface on a chamber component.

FIGS. 3A and 3B are an isometric view, and a side cross-sectional view, respectively, of one embodiment of a textured feature that may be utilized as the textured surface.

FIGS. 4A and 4B are a top plan view, and a aide cross-sectional view, respectively, of a textured surface that may be utilized as a textured surface on the chamber components shown in FIG. 1.

FIGS. 5A and 5B are a top plan view, and a side cross-sectional view, respectively, of a textured surface that may be utilized as a textured surface on the chamber components shown in FIG. 1.

FIGS. 6A and 6B are a top plan view, and a side cross-sectional view, respectively, of a textured surface that may be utilized as a textured surface on the chamber components shown in FIG. 1.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

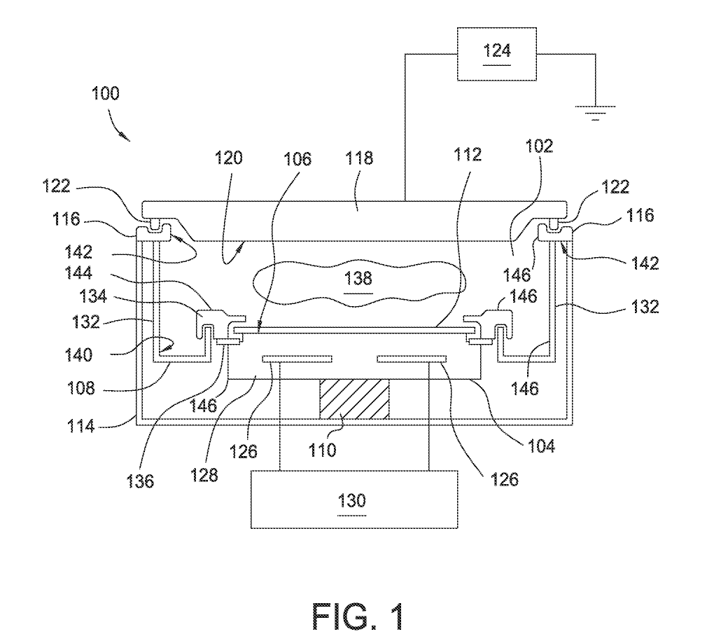

FIG. 1 is a simplified schematic cross-sections illustration of a process chamber exemplarily illustrated as a sputtering chamber 100 in which contamination may be reduced using embodiments described herein. Other process chambers, in which a substrate is exposed to one or more gas-phase materials, that may benefit from the surface treatment as described herein include physical vapor deposition (PVD) chambers and ion metal plasma (IMP) chambers, chemical vapor deposition (CVD) chambers, etch chambers, molecular beam epitaxy (MBE) chambers, atomic layer deposition (ALD) chambers, among others. The chamber may also be, for example, an etch chamber, such as a plasma etch chamber. Other examples of suitable process chambers include on implantation chambers, annealing chambers as well as other furnace chambers. Process chambers as well as the surface treatment process as disclosed herein may be commercially available from Applied Materials, Inc, of Santa Clara, Calif. Process chambers, as well as chamber components, available from other manufacturers may also benefit from the surface treatment process as described herein.

The sputtering chamber 100 comprises a vacuum chamber 182 and a substrate support 104 having a support surface 106. The substrate support 104 may be, for example, an electrostatic chuck. The sputtering chamber 100 further comprises a shield assembly 108 and a lift system 110. A substrate 112 (e.g., a semiconductor wafer) may be positioned upon the support surface 106 of the substrate support 104 during processing. Certain hardware such as gas inlet manifolds and/or vacuum pumps are omitted for clarity.

The exemplary vacuum chamber 102 includes a cylindrical chamber wall 114 and a support ring 116 which is mounted to the top of the chamber wall 114. The top of the chamber is closed by a target plate 118 which has an interior surface 120. The target plate 118 is electrically insulated from the chamber walls 114 by an annular insulator 122 that rests between the target plate 118 and the support ring 116. Generally, to ensure the integrity of the vacuum pressures in the vacuum chamber 102, o-rings (not shown) are used above and below the insulator 122 to provide a vacuum seal. The target plate 118 may be fabricated of a material that will become the deposition species, or it may contain a coating of the deposition species. To facilitate the sputtering process, a high voltage power supply 124 is connected to the target plate 118.

The substrate support 104 retains and supports substrate 112 within the vacuum chamber 182. The substrate support 104 may contain one or more electrodes 126 imbedded within a support body 128. The electrodes 128 are driven by a voltage from an electrode power supply 130 and, in response to application of the voltage, the substrate 112 may be clamped to the support surface 186 of the substrate support 104 by electrostatic forces. The support body 128 may comprise, for example, a ceramic material.

A wall-like cylindrical shield member 132 is mounted to the support ring 116. The cylindrical shape of the shield member 132 is illustrative of a shield member that conforms to the shape of the vacuum chamber 102 and/or the substrate 112. The shield member 132 may, of course, be of any shape. In addition to the shield member 132, the shield assembly 108 also includes an an nular deposition ring 134 having an inner diameter which is selected so that the ring fits over a peripheral edge of the substrate 112 without contacting the substrate 112 to function as a shadow ring. The deposition ring 134 rests upon an alignment ring 136 and the alignment ring 136 is supported by a flange that extends from the substrate support 104.

During as putter deposition process, process gas is supplied to the vacuum chamber 102 and power is supplied to target plate 118. The process gas is ignited into a plasma and is accelerated toward the target plate 118. The process gas dislodges particles from the target plate 118 and the particles deposit onto substrate 112 forming a coating of deposited material thereon.

White the shield assembly 108 generally confines the plasma and sputtered particles within a reaction zone 138, inevitably, sputtered particles, initially in a plasma or gaseous state, condense on various interior chamber surfaces. For example, sputtered particles may condense on an interior surface 140 of the shield assembly 108, on interior surfaces 120 of the target plate 118, on an interior surface 142 of the support ring 116, on a surface 144 of the deposition ring 134, as well as other interior chamber surfaces. Furthermore, other surfaces, such as the support surface 106 of the substrate support 104 may become contaminated either during or in between deposition sequences.

In general the term “interior surface” refers to any surface that has an interface with the vacuum chamber 102. A “chamber component” refers to any detachable element housed completely or partially within the vacuum chamber 102. The chamber component may be a vacuum chamber component, i.e. a chamber component placed within a vacuum chamber, such as, for example, the vacuum chamber 102. The condensed matter that forms on the interior surface of a chamber component, generally has only limited adhesion, and may release from the component and contaminate the substrate 112, which reduces yield of devices formed thereon.

In order to reduce the tendency of condensed matter to detach from a process chamber component, the chamber component, such as, for example, the shield assembly 108, the target plate 118, the support ring 116, the deposition ring 134, the support body 128, the alignment ring 136, or the substrate support 104 is provided with a textured surface 146. Other chamber components (not shown) may also include the textured surface 146 as described herein. For example, components such as a coil, coil supports, collimators, a shutter disk may be provided with the textured surface 146.

### Methods for Forming a Textured Surface

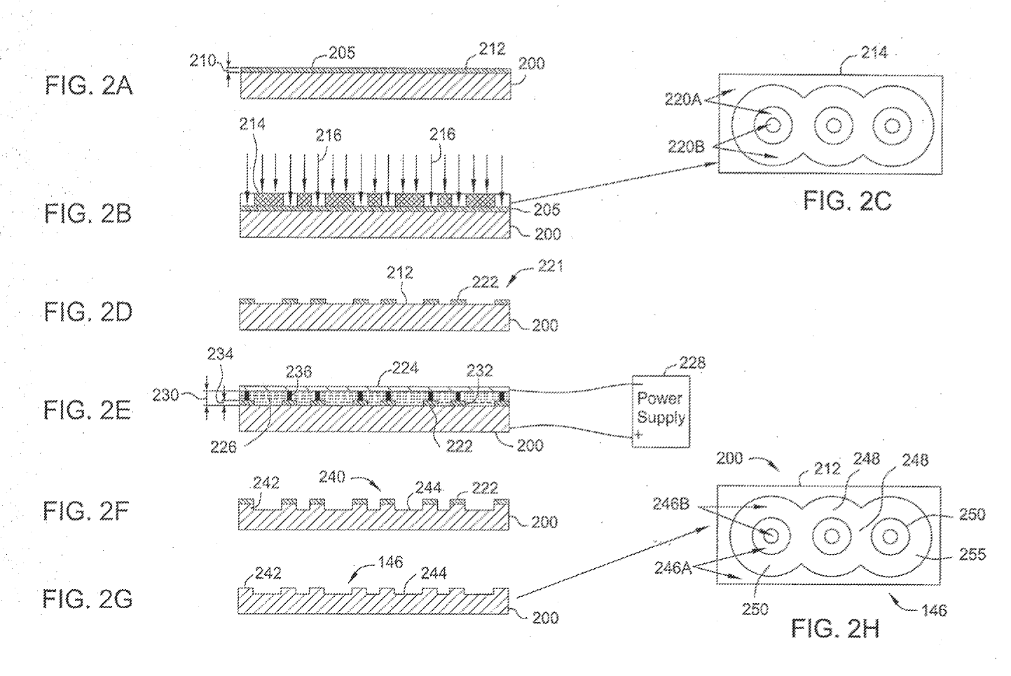

FIGS. 2A-2H are schematic views illustrating a process for forming a textured surface, such as the textured surface 146, on a chamber component, such as the shield assembly 108, the target plate 118, the support ring 116, the deposition ring 134, the support body 128, the alignment ring 136, or the substrate support 104 all shown in FIG. 1. In these Figures, the chamber component is referred to as a workpiece 200. The workplace 200 may be aluminum, stainless steel, titanium, or other material having qualities that would withstand processing in or on the vacuum chamber 102 of FIG. 1.

FIG. 2A is a schematic side view of a workpiece 200 having photoresist material 205 formed thereon. The photoresist material 205 may be a polyvinil acetate emulsion with a photo polymerizing resin. The photoresist material 205 may include a thickness 210 that is generally uniform across a surface 212 of the workpiece 200. In some embodiments, the thickness 210 may be about 10 microns (μm) to about 500 μm, such as, for example, about 0.1 millimeters (mm) to about 10 μm.

FIG. 28 is a schematic side view of the worlpiece 200 having patterned mask 214 disposed over the photoresist material 205, FIG. 2C is an enlarged top view of a portion of the patterned mask 214, and FIG. 2D is a schematic side view of the workpiece 200. Optical energy, such as ultraviolet light 216, impinges the photoresist material 205 and the patterned mask 214. The patterned mask 214 includes regions 220A where ultraviolet light 216 may pass through the patterned mask 214 and cure the photoresist material 205. The patterned mask 214 also includes regions 220B where ultraviolet light 213 may not pass and the underlying photoresist material 205 is not cured. Any uncured photoresist material 205 may be removed and a pattern 221 comprised of cured photoresist material 222, shown in FIG. 2D. The workpiece 200 with the pattern 220 may be placed in a tank (not shown) for further processing.

FIG. 2E is a schematic side view of the workpiece 200 having an electrode 224 placed over the surface 212 thereof. The electrode 224 may be in electrical communication with a power supply 223, which is also in electrical communication with the workpiece 200. An electrolyte 226 may be flowed between the surface 212 and the electrode 224. In some embodiments, the workpiece 200 is the anode and the electrode 224 is the cathode. The electrode 224 may be copper plate or a copper mesh. In some embodiments, a distance 230 between the surface 212 and the electrode 224 may be between about 0.1 mm to about 20 mm, and the electrode 224 may be parallel to the surface 212 during processing, in one embodiment, the electrode 224 may be placed directly on an upper surface 232 of the cured photoresist material 222. For example, a thickness 234 of the cured photoresist material 222 may be equal to the thickness 210 of the photoresist material 205 shown in FIG. 2A (e.g., about 0.1 mm to about 20 mm). In this manner, the cured photoresist material 232 may function as a spacer. In some embodiments, a spacer 236 may be placed between the upper surface 232 of the cured photoresist material 222 and the electrode 224 to maintain consistent spacing therebetween. The spacer 236 may be made of dielectric material, such as a polymer material or a ceramic material.

The electrolyte 226 may be a mixture or solution, which could be alkaline or acidic. An alkaline electrolyte may include NaCl (2-40%), NaBr (2-40%), NaNO₃ (2-40%), NaClO₃ (2-40%), (CH₂OH)₂ (10-50%), NaOH (3-20%). An acidic electrolyte may contain NaCl (2-40%) NaBr (2-40%), NaNO₃ (2-40%), NaClO₃ (2-40%), (CH₂OH)₂ (10-80%), HCl (3-20%). The electrolyte 226 may be flowed through a nozzle (not shown) under pressure or a magnetic stirrer may be used to maintain flow of the electrolyte 226. The power supply 228 may be set at a power of about 3 Volts direct current (DC) to about 100 Volts DC, such as, for example, about 10 Volts DC to about 20 Volts DC, up to and including about 3 Volts DC.

FIG. 2F is a schematic side view of the workplace 200 having a patterned surface 240 formed thereon after the etching process described is an enlarged to FIGS. 2A-2E. The patterned surface 240 includes a plurality of protrusions 242 and a plurality of depressions or grooves 244. The patterned surface also includes the cured photoresist material 222 remaining on the protrusions 242. The cured photoresist material 222 may be cleaned by a suitable solvent to provide the textured surface 146 on the workplace 200 as shown in FIGS. 2G and 2H.

FIG. 2G is a schematic side view of the workplace 200 having one embodiment of the textured surface 146 formed thereon. FIG. 2H is an enlarged top view of a portion of the workplace 200 and the textured surface 146. The textured surface 146 includes a plurality of raised features 246A surrounding and/or circumscribed by a plurality of depressions or grooves 246B. In some embodiments, at least a portion of the raised features 246A intersect at common regions 248. In other embodiments, at least a portion of the raised features 246A comprise circular structures 250. In some embodiments, at least a portion of the grooves 246B comprise arcuate structures 255.

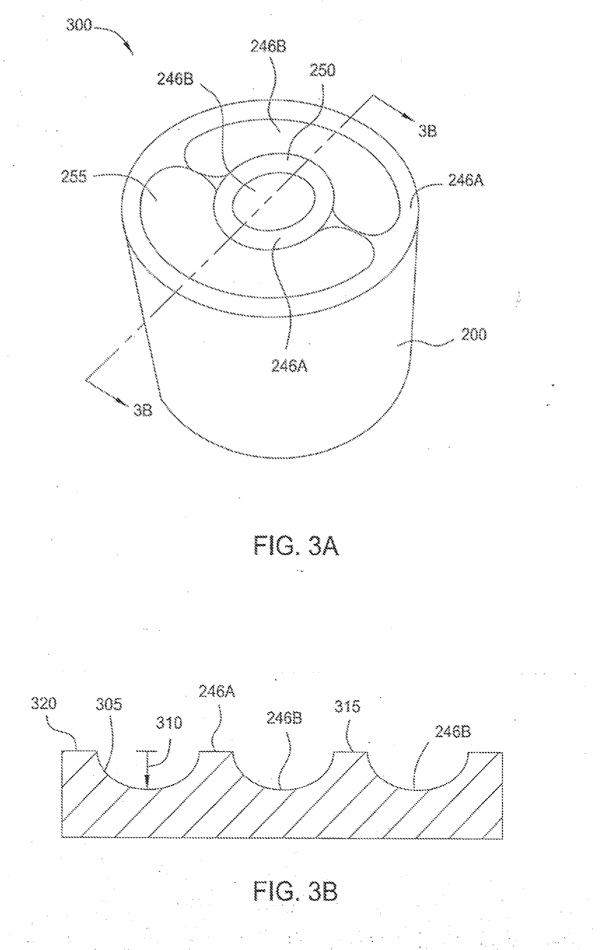

FIGS. 3A and 38 are an isometric view, and a side cross-sectional view, respectively, of a textured feature 300 that may be utilized as the textured surface 146 on a chamber component, such as the chamber components shown in FIG. 1. While a single textured feature 300 is shown, it is understood that other textured features similar to the textured feature 300 would surround and/or intersect the textured feature 300. The textured feature 300 may be formed on a workpiece 200 as described in FIGS. 2A, 2B and 2D-2G.

The textured feature 300 according to this embodiment includes a plurality of raised features 246A surrounding and/or circumscribed by a plurality of depressions or grooves 246B. At least a portion of the grooves 246B may be en arcuate structure 255 as viewed in plan view, in some embodiments, the arcuate structures 255 may be semicircular as shown. However, in other embodiments, the arcuate structures 255 may intersect such that the grooves 246B form a complete circle. At least a portion of the raised features 246A may comprise a circular structure 250 similar to the embodiment shown in FIG. 2H.

As shown in FIG. 3B, each of the grooves 246B may include, a curved surface 305. Each of the grooves 246B may be formed to a depth 310. The depth 310 of the grooves 246B may be about 0.1 mm, or greater, such as about 1 mm to about 2 mm, up to and including about 3 mm. The textured feature 300 may also include sharp edges or points 315 where the grooves 246B intersect with the raised features 246A. The points 315 as described herein include a sharp transition between the grooves 246B and the raised features 246A and the points 315 may lack any chamfer, bevel or radius. The points 315 may increase surface tension of any film that is deposited thereon thus increasing adhesion of the film to the textured feature 300. The grooves 246B may also include an average surface roughness (Re) that is about 10 μm to about 100 μm. The raised features 246A may also include surface 320 that may have a surface roughness of about 1 μm to about 10 μm.

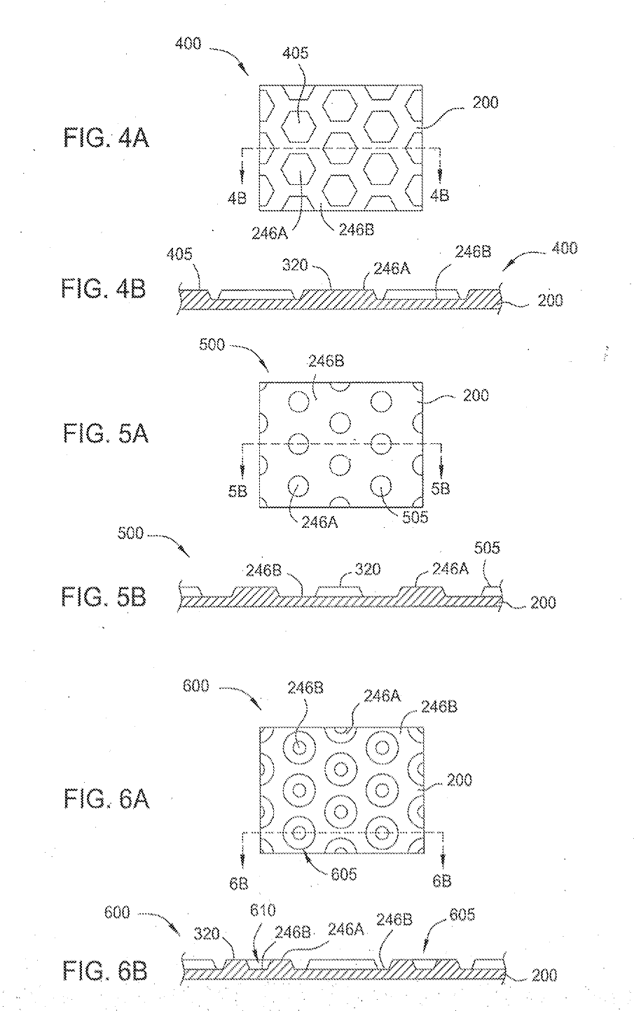

FIGS. 4A and 46 are a top plan view, and a side cross-sectional view, respectively, of a textured surface 400 that may be utilized as the textured surface 146 on a chamber component, such as the chamber components shown in FIG. 1. The textured surface 400 includes a plurality of raised features 246A surrounded by a plurality of depressions or grooves 246B. The plurality of raised features 246A according to this embodiment includes a plurality of protruding polygonal features 405, in the view shown in FIGS. 4A and 48, each of the plurality of protruding polygonal features 405 are shaped as hexagons, but other polygonal shapes may be formed. For example, the protruding polygonal features 405 may be formed as rectangular shapes, triangular shapes, octagonal shapes, diamond shapes, and combinations thereof. Depths of the grooves 246B may be about 700 μm to about 750 μm in some embodiments. A width or major dimension (flat side to flat side) of the protruding polygonal features 405 may be about 4 mm to about 4.25 mm in some embodiments.

FIGS. 5A and 5B are a top play view, and a side cross-sectional view, respectively, of a textured surface 500 that may be utilized as the textured surface 145 on a chamber component, such as the chamber components shown in FIG. 1. The textured surface 500 includes a plurality of raised features 246A surrounded by a plurality of depressions or grooves 246B. The plurality of raised features 246A according to this embodiment includes a plurality of protruding circular features 505. Depths of the moves 246B may be about 500 μm to about 650 μm in some embodiments. A width or major dimension (outer diameter) of the protruding circular features 505 may be about 800 μm to about 1,400 μm in some embodiments.

FIGS. 6A and 68 are a top plan view, and a side cross-sectional view, respectively, of a textured surface 600 that may be utilized as the textured surface 146 on a chamber component, such as the chamber components shown in FIG. 1. The textured surface 600 includes a plurality of raised features 246A surrounded by a plurality of depressions or grooves 246B. The plurality of raised features 246A according to this embodiment includes a plurality of dimple structures 605. Each of the dimple structures 605 may comprise a raised feature 246A and a groove 246B formed in the center of the raised feature 246A, in the embodiment shown, the dimple structures 605 are circular. However, in other embodiments, the dimple structures 605 may be polygonal in shape as shown and described in FIGS. 4A and 4B) with a recess 610 formed within the raised feature 246A. Depths of the grooves 246B and/or the recess 810 may be about 400 μm to about 650 μm in some embodiments. A width or major dimension (outer diameter) of the protruding circular features 505 may be about 500 μm to about 2,600 μm in some embodiments.

Embodiments of the textured surface 146, 400, 500 or 600 on chamber components as described herein increases adhesion of any films that may be deposited thereon. The increased adhesion prevents or minimizes deposited matter from detaching and creating particles that may be detrimental to devices formed on a substrate. This, in turn, may increase yield. The increased adhesion may also extend chamber maintenance intervals, which may increase productivity. The method for forming the textured surface 146 may also save time and be more environmentally friendly than other methods, such as chemical etching. For example, a titanium workpiece was textured according to the method described herein, and the etch rate was about 1 mm per 20 minutes, as compared to an acid (HNO₃) etch, which is a few microns per hour.

While the foregoing is directed to embodiments of the present disclosure, other and further embodiments of the disclosure thus may be devised without departing from the basic scope thereof, and the scope thereof is determined by the claims that follow.

1. A method for a textured surface on a chamber component, the method comprising:
providing a chamber component;
applying a layer of a photoresist to a surface of the chamber component;
exposing a portion of the photoresist to optical energy using a mask to cure a portion of the photoresist;
removing uncured photoresist from the surface; and
electrochemically etching the chamber component to form a textured surface on the chamber component.

2. The method of claim 1, wherein the chamber component comprises an anode during the etching.

3. The method of claim 1, wherein the chamber component comprises a shield assembly, a target plate, a support ring, a deposition ring, a support body, an alignment ring, or a substrate support.

4. The method of claim 1, wherein the chamber component comprises aluminum, stainless steel, or titanium.

5. The method of claim 1, wherein the textured surface comprises a plurality of circular structures.

6. The method of claim 5, wherein at least a portion of the circular structures intersect.

7. The method of claim 5, wherein the circular structures include a recess formed therein.

8. The method of claim 1, wherein the textured surface comprises a plurality of raised features surrounding and/or circumscribed by a plurality grooves.

9. The method of claim 8, wherein at least a portion of the grooves intersect.

10. A chamber component for a processing chamber, the component comprising:
a textured surface comprising a plurality of textured features formed by an electrochemical etching process, each of the textured features comprising:
a plurality of raised features surrounding and/or circumscribed by a plurality grooves, and at least a portion of the grooves intersect.

11. The component of claim 10, wherein the textured surface is formed on a shield assembly, a target plate, a support ring, a deposition ring, a support body, an alignment ring, or a substrate support.

12. The component of claim 10, wherein the textured surface is formed on an aluminum material, a stainless steel material, or a titanium material.

13. The component of claim 10, wherein the textured surface comprises a plurality of circular structures.

14. The component of claim 10, wherein the grooves include a curved surface.

15. The component of claim 14, wherein the curved surface intersects with the raised feature at a sharp point.

16. The component of claim 10, wherein the grooves are formed at a depth of about 0.1 millimeters to about 2 millimeters.

17. A chamber component for a processing chamber, the component comprising:
a metallic material formed as a chamber component;
a textured surface comprising a plurality of textured features formed by an electrochemical etching process on the metallic material, each of the textured features comprising:
a plurality of raised features surrounding and/or circumscribed by a plurality grooves, each of the grooves including a curved surface intersecting with the raised feature at a sharp point.

18. The component of claim 17, wherein the chamber component comprises one of a shield assembly, a target plate, a support ring, a deposition ring, a support body, an alignment ring, or a substrate support.

19. The component of claim 17, wherein the metallic material comprises an aluminum material, a stainless steel material, or a titanium material.

20. The component of claim 17, wherein the textured surface comprises a plurality of circular structures.
